(19) United States
(12) Patent Application Publication
(10) Pub. No.: US 2016/0042813 A1
(43) Pub. Date: Feb. 11, 2016

(54) SEMICONDUCTOR MEMORY DEVICE AND METHOD FOR TESTING REDUNDANCY WORD LINE

(71) Applicant: SK hynix Inc., Gyeonggi-do (KR)

(72) Inventor: Kwi-Dong KIM, Gyeonggi-do (KR)

(21) Appl. No.: 14/566,375

(22) Filed: Dec. 10, 2014

(30) Foreign Application Priority Data
Aug. 5, 2014 (KR) 10-2014-0100366

(51) Int. Cl. G11C 29/00; G11C 17/18; G11C 29/04; G11C 17/16

(52) U.S. Cl. CPC G11C 29/838; G11C 17/16; G11C 17/18; G11C 29/04

(57) ABSTRACT

A semiconductor memory device includes a plurality of redundancy cells suitable for repairing a defective cell of a plurality of normal cells, a defective redundancy cell information storing circuit block suitable for detecting whether the redundancy cells are defective and storing information on a redundancy cell that is detected to be defective, and a defective redundancy cell rupture circuit block suitable for performing a disable rupture operation on the redundancy cell that is detected to be defective.

### CROSS-REFERENCE TO RELATED APPLICATIONS

The present application claims priority of Korean Patent. Application No. 10-2014-0100366, filed on Aug. 5, 2014, which is incorporated herein by reference in its entirety.

### BACKGROUND

1. Field

Exemplary embodiments of the present invention relate to a semiconductor design technology and, more particularly, to a semiconductor memory capable of controlling redundancy cells.

2. Description of the Related Art

During the semiconductor memory fabrication process a probe test (PT) may be performed on semiconductor memory cells. When a defective memory cell is detected as a result of the probe test, a repair operation using a redundancy memory cell is performed to replace the defective memory cell with a redundancy memory cell. Subsequently, a package test (PKT) may be performed to test the packaged semiconductor memory. However, there is no way to know whether redundancy memory cells are defective in the package test Therefore, there is concern that the reliability of the redundancy cells is not ensured by the package test since the repair operation is performed without knowing whether the redundancy memory cell is defective. This is described below with reference to FIG. 1.

FIG. 1 shows a repair state of a semiconductor memory device after a test is performed, according to prior art.

Referring to FIG. 1, a first stage block 110 represents a state of the semiconductor memory device performing a repair operation based on a first test. TEST0, and a second stage block 120 represents a state of the semiconductor memory device performing a repair operation based on a second test TEST1. The first test TEST0 may be a probe test, and the second test TEST1 may be a package test.

The semiconductor memory device may include first to eighth normal cells NOR_CELL_0 to NOR_CELL_7 and first to fourth redundancy cells RED_CELL_0 to RED_CELL_3.

A repair operation may be performed on the first to eighth normal cells NCR_CELL_0 to NOR_CELL_7 based on the first to fourth redundancy cells RED_CELL_0 to RED_CELL_3 during the first test TEST0. For example, when a defect is detected in the third normal cell NOR_CELL_2 among the first to eighth normal cells NOR_CELL_0 to NOR_CELL_7 during the first test TEST0, the third normal cell NOR_CELL_2 may be repaired with the first redundancy cell RED_CELL_0 among the first to fourth redundancy cells RED_CELL_0 to RED_CELL_3.

Subsequently, the second test TEST1 is performed. As the second test TEST1. is the package test, it is not possible to store information on whether the redundancy cells RED_CELL_0 to RED_CELL_3 are defective cells due to restraints on package test equipment Thus, when the redundancy cells RED_CELL_0 to RED_CELL_3 are sequentially used to replace defective cells of the normal cells NOR_CELL_0 to NOR_CELL_7, the second redundancy cell RED_CELL_1 among the redundancy cells RED_CELL_0 to RED_CELL_3 may be used for a subsequent repair operation in the second test TEST1 since the first redundancy cell RED_CELL_0 is used to repair the third normal cell NOR_CELL_2 in the first test TEST0.

The second redundancy cell RED_CELL_1 is detected as a defective cell during the second test TEST1. According to prior art, the fact that the second redundancy cell RED_CELL_1 is a defective cell cannot be stored although the second redundancy cell RED_CELL 1 is detected as a defective cell, and therefore, the second redundancy cell RED_CELL_1 detected as a defective cell is not replaced with another redundancy cell. Consequently, when the fifth normal cell NOR_CELL_4 is detected as a defective cell and repaired based on the second redundancy cell RED_CELL_1, reliability of the repair operation on the fifth normal cell NOR_CELL_4 is not secured.

In other words, since it is impossible to store information on whether the redundancy cell passes or fails during the second test, the package test, there may be concern that the reliability of the redundancy cells used during subsequent processes are not secured.

### SUMMARY

Exemplary embodiments of the present invention are directed to a semiconductor memory device that may store a test result of a redundancy cell during a package test and control the redundancy cell.

In accordance with an embodiment of the present invention, a semiconductor memory device includes a plurality of redundancy cells suitable for repairing a defective cell of a plurality of normal cells, a defective redundancy cell information storing circuit block suitable for detecting whether the redundancy cells are defective and storing information on a redundancy cell that is detected to be defective among the redundancy cells, and a defective redundancy cell rupture circuit block suitable for performing a disable rupture operation on the redundancy cell that is detected to be defective.

The defective redundancy cell information storing circuit block may include an address decoding unit suitable for sequentially decoding redundancy addresses corresponding to the redundancy cells, a detection unit suitable for detecting whether the redundancy cells are defective, and a storing unit suitable for sequentially storing failure information of the redundancy cells outputted from the detection unit.

The storing unit may include a plurality of latch circuits, equal in number to the redundancy cells.

The defective redundancy cell rupture circuit block may disable a fuse set corresponding to the redundancy cell that is detected to be defective.

The defective redundancy cell rupture circuit block may include a rupture control unit suitable for generating a rupture enable signal for controlling a disable rupture of the fuse set based on the failure information of the redundancy cells, a rupture Array E-Fuse (ARE) decoding unit suitable for decoding a fuse set address corresponding to the fuse set, and an ARE core unit suitable for disable-rupturing the fuse set in response to the rupture enable signal.

The defective redundancy cell information storing circuit block may detect whether the redundancy cells pass or fail during a package test operation.

In accordance with another embodiment of the present invention, a method for testing a redundancy word line includes: decoding a redundancy address for selecting the redundancy word line during a redundancy test operation, detecting whether data stored in the redundancy word line corresponding to a decoded redundancy address passes or fails, sequentially latching information on whether the data passes or fails in a latch circuit based on the decoded redundancy address, and controlling a disable rupture of the redundancy word line based on latched information.

The controlling of the disable rupture of the redundancy word line may include performing the disable rupture of the redundancy word line when the data stored in the redundancy word line is a failure.

The performing of the disable rupture of the redundancy word line may include disabling a fuse set corresponding to the redundancy word line.

The plurality of redundancy word lines may be tested as the redundancy word line, and the sequential latching of the information may be performed through latch circuit, equal in number to the redundancy word lines.

The redundancy test operation may be included in a package test operation.

### BRIEF DESCRIPTION OF THE DRAWINGS

FIG. 1 shows a repair state of a semiconductor memory device after a test is performed according to prior art.

FIG. 2 is a block diagram illustrating a semiconductor memory device in accordance with an embodiment of the present invention.

FIG. 3 shows a repair state of the semiconductor memory device shown in FIG. 2 after a test is performed.

### DETAILED DESCRIPTION

Exemplary embodiments of the present invention are described below in more detail with reference to the accompanying drawings. These embodiments are provided so that this disclosure is thorough and complete, and fully convey the scope of the present invention to those skilled in the art. All “embodiment” referred to in this disclosure refer to embodiments of the inventive concept disclosed herein. The embodiments presented are merely examples and are not intended to limit the inventive concept.

The drawings are not necessarily to scale and, in some instances, proportions may have been exaggerated in order to clearly illustrate features of the embodiments. Throughout the disclosure, like reference numerals correspond directly to the like parts in the various figures and embodiments of the present invention.

It is also noted that in this specification, “connected/coupled” refers to one component not only directly coupling another component but also indirectly coupling another component through an intermediate component. In addition, a singular form may include a plural form as long as it is not specifically mentioned in a sentence.

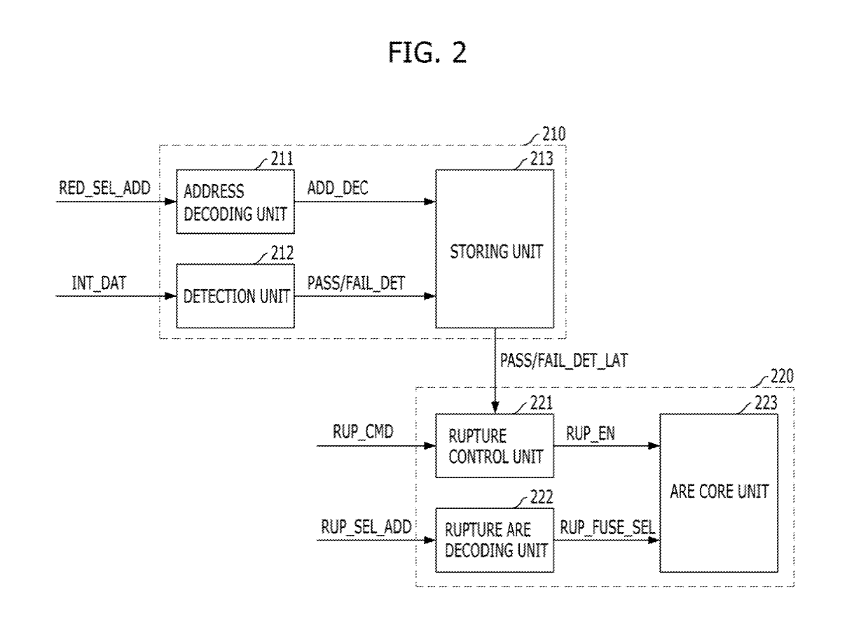

FIG. 2 is a block diagram illustrating a semiconductor memory device in accordance with an embodiment of the present invention.

Referring to FIG. 2, the semiconductor memory device may include a defective redundancy cell storing circuit block 210 and a defective redundancy cell rupture circuit block 220.

In accordance with an embodiment of the present invention, the semiconductor memory device may read data stored in each of a plurality of redundancy word lines and detect whether the redundancy word lines pass or fail during a test operation of the redundancy word lines. Whether the redundancy word lines pass or fail indicates whether a plurality of redundancy cells corresponding to the redundancy word lines pass or fail.

The defective redundancy cell storing circuit block 210 detects whether the redundancy cells pass or fail and stores information on a redundancy cell that is detected as a defective cell among the redundancy cells. The defective redundancy cell storing circuit block 210 may include an address decoding unit 211, a detection unit 212 and a storing unit 213.

The address decoding unit 211 may sequentially receive and decode a redundancy address RED_SEL_ADD for selecting the redundancy word lines. A decoding address ADD_DEC decoded and outputted by the address decoding unit 211 may be latched in the storing unit 213.

The detection unit 212 may determine whether internal data INT_DAT passes or fails and outputs pass/fail detection information PASS/FAIL_DET. The internal data INT_DAT may be data stored in a redundancy word line in response to the redundancy address RED_SEL_ADD. In other words, whether the internal data INT_DAT passes or fails is the same as whether the redundancy word line passes or fails. Thus, since the redundancy address RED_SEL_ADD and the internal data INT_DAT are information on the same redundancy word line, they may be inputted at the same time.

The storing unit 213 may sequentially receive and latch the decoding address ADD_DEC that is decoded in and outputted from the address decoding unit 211 and the pass/fail detection information PASS/FAIL_DET that is outputted from the detection unit 212. The storing unit 213 may include a plurality of latch circuits (not shown), and the latch circuits may be formed corresponding to the redundancy word lines, respectively. For example, when the number of the redundancy word lines is 4, the storing unit 213 may include 4 latch circuits. When the pass/fail detection information PASS/FAIL_DET is a pass, the storing unit 213 may latch a value of a logic high level, and when the pass/fail detection information PASS/FAIL_DET is a failure, the storing unit 213 may latch a value of a logic low level. For example, when a first redundancy word line is detected as a defective word line among the redundancy word lines, a first latch circuit corresponding to the first redundancy word line among the latch circuits may latch the value of the logic low level, and the other latch circuits corresponding to the other redundancy word lines may latch the value of the logic high level. The storing unit 213 may latch the pass/fail detection information PASS/FAIL_DET in the latch circuits and sequentially output a latched pass/fail detection information PASS/FAIL_DET_LAT.

The defective redundancy cell rupture circuit block 220 performs a disable rupture operation on the redundancy cell that is detected as a defective cell. The defective redundancy cell rupture circuit block 220 may include a rupture control unit 221, a rupture Array E-Fuse (ARE) decoding unit 222 and an Array E-Fuse (ARE) core unit 223.

The rupture control unit 221 may perform a control to enable or disable a corresponding redundancy word line based on the latched pass/fail detection information PASS/FAIL_DET_LAT outputted from the storing unit 213 in response to a rupture command RUP_CMD, The rupture command RUP_CMD is a command for disable-rupturing a corresponding redundancy word line when the latched pass/fail detection information PASS/FAIL_DET_LAT is a failure. The rupture control unit 221 may generate a rupture enable signal RUP EN for controlling a disable rupture of a corresponding redundancy word line among the redundancy word lines based on the latched pass/fail detection information PASS/FAIL_DET_LAT. When the latched pass/fail detection information PASS/FAIL_DET_LAT is a pass, in other words, when it has the value of a logic high level, the rupture control unit 221 may control the rupture enable signal RUP_EN to have the value of a logic low level to not disable-rupture the corresponding redundancy word line. When the latched pass/fail detection information PASS/FAIL_DET_LAT is a failure, in other words, when it has the value of a logic low level, the rupture control unit 221 may control the rupture enable signal RUP_EN to have the value of a logic high level to disable-rupture the corresponding redundancy word line, The rupture control unit 221 may be formed of a combination of logic circuits.

The rupture Array E-Fuse (ARE) decoding unit 222 may decode a rupture select address RUP_SEL_ADD and generate a rupture fuse select signal RUP_FUSE_SEL for selecting a fuse corresponding to a corresponding redundancy word line among the redundancy word line in the ARE core unit 223, The rupture select address RUP_SEL_ADD indicates redundancy addresses corresponding to the redundancy word lines. The rupture fuse select signal RUP_FUSE_SEL may be outputted at the same time as the rupture enable signal RUP_EN outputted from the rupture control unit 221 and control a rupture operation of the ARE core unit 223.

The ARE core unit 223 may perform a rupture operation of a redundancy word line corresponding to the rupture fuse select signal RUP_FUSE_SEL in response to the rupture enable signal RUP_EN. When the rupture enable sign& RUP_EN has the value of a logic low level, the ARE core unit 223 may not perform a disable rupture operation of the redundancy word line corresponding to the rupture fuse select signal RUP_FUSE_SEL and when the rupture enable signal

RUP EN has the value of a logic high level, the AR E core unit 223 may perform the disable rupture operation of the redundancy word line corresponding to the rupture fuse select signal RUP_FUSE_SEL, other words, the ARE core unit 223 may control a rupture of a fuse corresponding to a corresponding redundancy word line based on a pass/fail detection result of the redundancy word line.

To sum up, when a test operation is performed on the redundancy word lines, whether the redundancy word lines pass or fail may be detected, and a disable rupture operation may be performed on the corresponding word line based on the pass/fail detection information PASS/FAIL_DET. When the redundancy word line fails, the redundancy word line may be controlled to be disabled as the disable rupture operation is performed on the fuse corresponding to the redundancy word line. Therefore, when a repair operation is performed through a normal test after the test operation is performed on the redundancy word lines, a redundancy word line that is detected as a defective word line among the redundancy word lines is disabled, and is not used to repair a defective normal word line. As a result, the reliability of the repair operation may be secured.

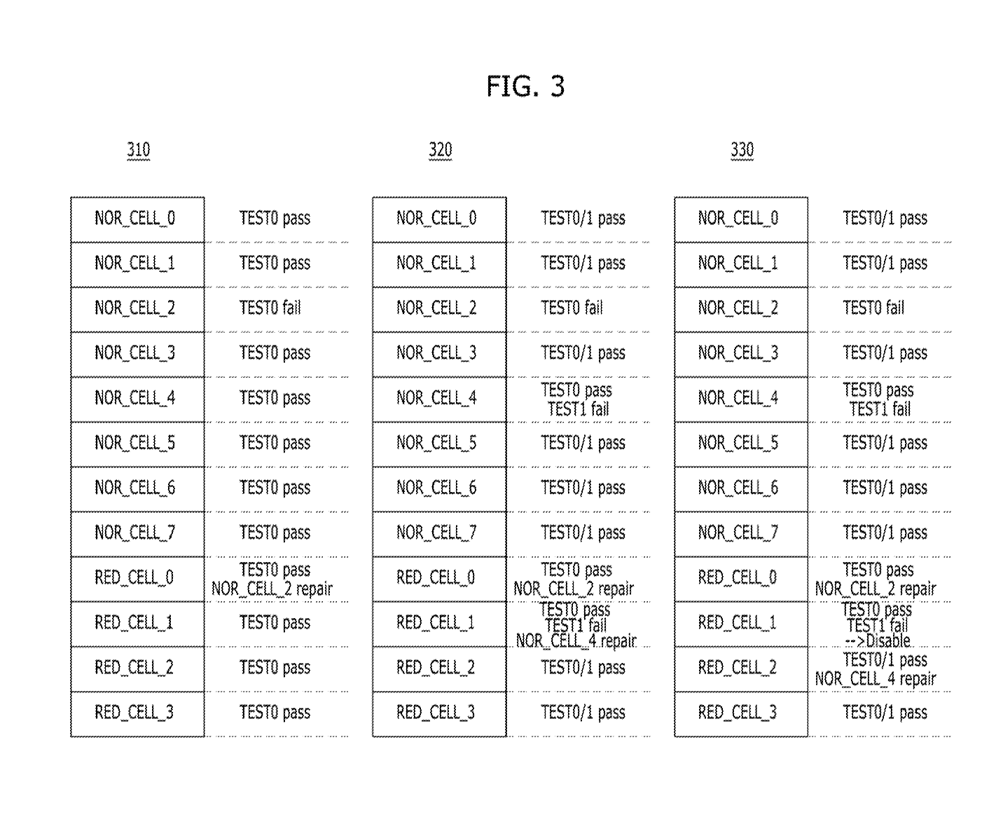

FIG. 3 shows a repair state of the semiconductor memory device shown in FIG. 2 after a test is performed.

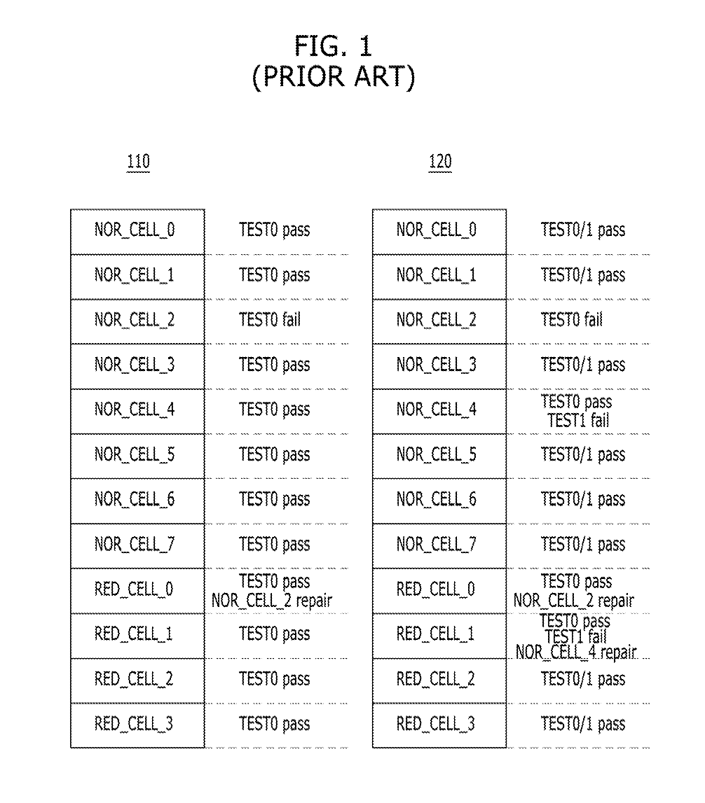

Since a first stage block 310 and a second stage block 320 are the same as the first stage block 110 and the second stage block 120 shown in FIG. 1 and they are shown to be compared to a third stage block 330 in FIG. 3, a detailed description on the first stage block 310 and the second stage block 320 is omitted herein.

The third stage block 330 shows a state of the semiconductor memory device performing the repair operation based on whether the redundancy cell passes or fails. A first test TEST0 may be a probe test, and a second test TEST1 may be a package test.

The semiconductor memory device performing first test TEST0 and the second test TEST1 may include first to eighth normal cells NOR_CELL_0 to NOR_CELL_7 and first to fourth redundancy cells RED_CELL_0 to RED_CELL_3.

The result value of the test on the first to fourth redundancy cells RED_CELL_0 to RED_CELL_3 may be latched in the storing unit 213 shown in FIG. 2. As a result of the second test TEST1, the second redundancy cell RED_CELL_1 that is detected as a defective cell among the first to fourth redundancy cells RED_CELL_0 to RED_CELL_3 may be disabled through the rupture control unit 221 shown in FIG. 2. When the repair operation is performed on the fifth normal cell NOR_CELL_4 that is detected as a defective cell among the first to eighth normal cells NOR_CELL_0 to NOR_CELL_7 during the second test TEST1, the repair operation may be performed by the third redundancy cell RED_CELL_2 which is passed and enabled, not the second redundancy cell RED_CELL_1 which is detected as a defective cell.

To sum up, as the result value of the test on the redundancy cell is stored, and the redundancy cell that is detected as a defective cell is disabled when the second test Test2, which is the package test, is performed, the reliability of the repair operation may be secured.

To this end, the semiconductor memory device in accordance with the embodiment of the present invention may operate in the following method.

The method of operating the semiconductor memory device may include decoding a redundancy address for selecting a redundancy word line during a redundancy test operation among the package test operation, detecting whether the data stored in the redundancy word line corresponding to the redundancy address passes or fails, sequentially latching the pass/fail detection information in a latch circuit based on the redundancy address, and controlling a disable rupture operation of the redundancy word line based on the latched pass/fail detection information.

In accordance with the embodiments of the present invention, as enabling of redundancy cells is selectively controlled based on whether the redundancy cell passes or fails, the reliability of semiconductor memory device repair operations may be improved, and the reliability of redundancy cells during subsequent processes may be improved as well.

While the present invention has been described with respect to specific embodiments, the embodiments are not intended to be restrictive, but rather descriptive. Further, it is noted that the present invention may be achieved in various ways through substitution, change, and modification, by those skilled in the art without departing from the scope of the present invention as defined by the following claims.

What is claimed is:

1. A semiconductor memory device, comprising:
a plurality of redundancy cells suitable for repairing a defective cell of a plurality of normal cells;
a defective redundancy cell information storing circuit block suitable for detecting whether the redundancy cells are defective and storing information about a redundancy cell that is detected to be defective; and
a defective redundancy cell rupture circuit block suitable for performing a disable rupture operation on the redundancy cell that is detected to be defective.

2. The semiconductor memory device of claim 1, wherein the defective redundancy cell information storing circuit block includes:
an address decoding unit suitable for sequentially decoding redundancy addresses corresponding to the redundancy cells;
a detection unit suitable for detecting whether the redundancy cells are defective; and
a storing unit suitable for sequentially storing failure information of the redundancy cells outputted from the detection unit.

3. The semiconductor memory device of claim 2, wherein the storing unit includes a plurality of latch circuits, which are equal in number to the redundancy cells.

4. The semiconductor memory device of claim 2, wherein the defective redundancy cell rupture circuit block disables a fuse set corresponding to the redundancy cell that is detected to be defective.

5. The semiconductor memory device of claim 4, wherein the defective redundancy cell rupture circuit block includes:
a rupture control unit suitable for generating a rupture enable signal for controlling a disable rupture of the fuse set based on the failure information of the redundancy cells;
a rupture Array E-Fuse (ARE) decoding unit suitable for decoding a fuse set address corresponding to the fuse set; and
an ARE core unit suitable for disable-rupturing the fuse set in response to the rupture enable signal.

6. The semiconductor memory device of claim wherein the defective redundancy cell information storing circuit block detects whether the redundancy cells pass or fail during a package test operation.

7. A method for testing a redundancy word line, comprising:
decoding a redundancy address for selecting the redundancy word line during a redundancy test operation;
detecting whether data stored in the redundancy word line corresponding to a decoded redundancy address passes or fails;
sequentially latching information on whether the data passes or fails in a latch circuit based on the decoded redundancy address; and
controlling a disable rupture of the redundancy word line based on the latched information.

8. The method of claim 7, wherein the controlling of the disable rupture of the redundancy word line includes:
performing the disable rupture of the redundancy word line when the data stored in the redundancy word line is a failure.

9. The method of claim 8, wherein the performing of the disable rupture of the redundancy word line includes:
disabling a fuse set corresponding to the redundancy word line.

10. The method of claim 7, wherein a plurality of redundancy word lines are tested as the redundancy word line, and the sequentially latching of the information is performed through latch circuits that are equal in number to the redundancy word lines.

11. The method of claim 7, wherein the redundancy test operation is included in a package test operation.
